(19) United States
(12) Patent Application Publication
(10) Pub. No.: US 2025/0349770 A1
(43) Pub. Date: Nov. 13, 2025

(54) SEMICONDUCTOR DEVICE

(71) Applicant: Samsung Electronics Co., Ltd., Suwon-si (KR)

(72) Inventors: Dongwoo Kim, Suwon-si (KR); Seyeong Seok, Suwon-si (KR); Daseul Lee, Suwon-si (KR); Jonghyeon Chang, Suwon-si (KR); Daeeun Heo, Suwon-si (KR)

(21) Appl. No.: 18/948,588

(22) Filed: Nov. 15, 2024

(30) Foreign Application Priority Data
May 13, 2024 (KR) 10-2024-0062667

(51) Int. Cl. H01L 23/00

(52) U.S. Cl. CPC H01L 24/06; H01L 24/05; H01L 2224/05554; H01L 2224/06132; H01L 2224/06142; H01L 2224/06152; H01L 2224/06179

(57) ABSTRACT

A semiconductor device includes a plurality of connection pads having a polygonal planar shape, and edges defining a front surface on which the plurality of connection pads are disposed. The plurality of connection pads include reference pads in which a first center line passing through a vertex of the planar shape coincides with a reference line orthogonal to the adjacent edges, and first to n^{th} rotated pads sequentially disposed from one side of one of the reference pads, and each second center line passing through the vertex of the planar shape of the first to n^{th} rotated pads has a rotation angle (βn) according to the following equation with respect to the reference line given by βn=n(45°/N). In the equation above, n represents an arrangement order of the first to n^{th} rotated pads, and N is the number of the first to n^{th} rotated pads.

### CROSS-REFERENCE TO RELATED APPLICATION(S)

This application claims benefit of priority to Korean Patent Application No. 10-2024-0062667, filed on May 13, 2024 in the Korean Intellectual Property Office, the content and the inventive concept of which are incorporated herein by reference in their entirety.

### BACKGROUND

The present inventive concept relates to a semiconductor device.

In accordance with the trend toward miniaturization and high density of semiconductor devices, connection pads of semiconductor devices are formed to have finer pitches. Connection pads arranged at a fine pitch may increase an area of the connection pads at a peeling boundary of a dicing tape, thereby hindering peeling of the dicing tape and causing a decrease in yield.

### SUMMARY

An aspect of the present inventive concept is to provide a semiconductor device having improved process efficiency.

According to an aspect of the present inventive concept, a semiconductor device is provided, the semiconductor device includes a circuit layer including a front surface and a plurality of circuit edges defining the front surface; and a plurality of conductive pads disposed on the front surface and having a polygonal planar shape. The plurality of conductive pads include a plurality of reference pads and a plurality of rotated pads. Each of the plurality of reference pads includes a reference pad surface, reference pad edges defining the reference pad surface, reference pad vertices and a reference pad diagonal which is a line segment joining a predetermined pair of the reference pad vertices. The reference pad diagonal is disposed orthogonally to one of the plurality of circuit edges. Each of the plurality of rotated pads includes a rotated pad surface, rotated pad edges defining the rotated pad surface, rotated pad vertices and a rotated pad diagonal which is a line segment joining a predetermined pair of the reference pad vertices. The plurality of rotated pads include a first group of rotated pads including first to nth rotated pads. The plurality of reference pads include a first reference pad. The first to n^{th} rotated pads are disposed in a series from one side of the first reference pad, with respect to one of the plurality of circuit edges, each of the first to n^{th} rotated pads has a rotation angle (βn) substantially given by an equation βn=n(45°/N). In the equation, n represents an arrangement order of the first to n^{th} rotated pads, and N is a number of the first to n^{th} rotated pads.

According to an aspect of the present inventive concept, a semiconductor device is provided, the semiconductor device includes a circuit layer including a front surface, circuit edges defining the front surface, front surface vertices and a front surface diagonal which is a line segment joining a predetermined pair of the front surface vertices; and a plurality of conductive pads disposed on the front surface. Each conductive pad having a square planar shape. The plurality of conductive pads include reference pads and rotated pads. The rotated pads include first to n^{th} rotated pads. The first to n−1th rotated pads are disposed between the reference pads and the front surface diagonal. Each of the reference pads includes a reference pad surface and reference pad edges defining the reference pad surface. For each reference pad, a predetermined one of the reference pad edges of each reference pad has a reference angle with respect to a particular one of the circuit edges. Each of the rotated pads includes a rotated pad surface and rotated pad edges defining the rotated pad surface. For each rotated pad, a predetermined one of the rotated pad edges has an inclination angle with respect to the particular one of the circuit edges, and the inclination angle is smaller than the reference angle. As the rotated pads get closer to the front surface diagonal, the inclination angles of the rotated pads decrease.

According to an aspect of the present inventive concept, a semiconductor device is provided, the semiconductor device includes a circuit layer including a front surface, circuit edges defining the front surface, front surface vertices and a front surface diagonal which is a line segment joining a predetermined pair of the front surface vertices, and a plurality of conductive pads disposed on the front surface and having a polygonal planar shape. The plurality of conductive pads include reference pads and rotated pads. Each of the reference pads includes a reference pad surface and reference pad edges defining the reference pad surface. Each of the rotated pads includes a rotated pad surface, rotated pad edges defining the rotated pad surface, rotated pad vertices and a reference pad diagonal which is a line segment joining a predetermined pair of the reference pad vertices. Each of the reference pads includes at least one reference pad edge having a reference angle with respect to a particular one of the circuit edges substantially given by a first equation θ=180°/z. In the first equation, z is the number of reference pad edges of one of the reference pads. At least one of the rotated pads includes the reference pad diagonal which aligns with the front surface diagonal.

### BRIEF DESCRIPTION OF DRAWINGS

The above and other aspects, features, and advantages of the present disclosure will be more clearly understood from the following detailed description, taken in conjunction with the accompanying drawings:

FIG. 1A is a perspective view of a semiconductor device according to an example embodiment, FIG. 1B is a cross-sectional view taken along line I-I′ of FIG. 1A, and FIG. 1C is a partially enlarged view of region ‘K’ of FIG. 1A;

FIG. 2A is a plan view of a semiconductor device according to an example embodiment, FIGS. 2B and 2C are partially enlarged views of region ‘A’ of FIG. 2A, and FIG. 2D is a plan view illustrating first and second regions;

FIG. 3 is a partially enlarged view illustrating a semiconductor device of a modified example;

FIG. 4A is a plan view of a semiconductor device according to an example embodiment, and FIG. 4B is a partially enlarged view of region ‘B’ of FIG. 4A;

FIG. 5 is a plan view of a semiconductor device according to an example embodiment;

FIGS. 6A to 6C are diagrams for illustrating a peeling process of a dicing tape;

FIG. 7A is a diagram illustrating a peeling boundary of a dicing tape in a semiconductor device in an example, and FIGS. 7B and 7C are drawings illustrating a peeling boundary of a dicing tape in a semiconductor device in first and second comparative examples; and

FIG. 8A is a graph illustrating peeling boundary density of a connection pad in the example of FIG. 7A and the first comparative example of FIG. 7B, and FIG. 8B is a graph illustrating peeling boundary density of the connection pad in the example of FIG. 7A and the first and second comparative examples of FIGS. 7B and 7C.

### DETAILED DESCRIPTION

Hereinafter, with reference to the accompanying drawings, preferred embodiments of the present inventive concept will be described as follows.

Unless otherwise specified, spatially relative terms, such as “beneath,” “below,” “lower,” “above,” “upper,” “top,” “bottom,” “front,” “rear,” “edge”, “side” and the like, may be used herein for ease of description to describe one element's or feature's relationship to another element(s) or feature(s) such as illustrated in the figures, for example. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

In addition, an ordinal number such as “first,” “second,” “third”, and the like may be used as a label of specific elements, steps, directions, and the like to distinguish various elements, steps, and directions from each other. Terms not described using “first”, “second”, and the like, in the specification may still be referred to as “first” or “second” in the claims. Also, a term referenced by a particular ordinal number (e.g., “first” in a particular claim) may be recited elsewhere by a different ordinal number (e.g., “second” in a specification or the other claim).

Items described in the singular herein may be provided in plural, as can be seen, for example, in the drawings. Thus, the description of a single item that is provided in plural should be understood to be applicable to the remaining plurality of items unless context indicates otherwise.

In drawings and discussion thereon below, items common may retain the same or similar reference designation, unless the context clearly indicates otherwise. Accordingly, the present disclosure may repeat reference numerals and/or letters in the various examples and drawings, such that like reference numerals and/or letters between figures indicate like items, elements, steps and so on. Accordingly, contents duplicate with what have been described one drawing may be briefly described or descriptions thereof may be omitted. This repetition of like reference numerals and/or letters is for the purpose of simplicity and clarity and does not in itself dictate a relationship between the various embodiments and/or configurations discussed.

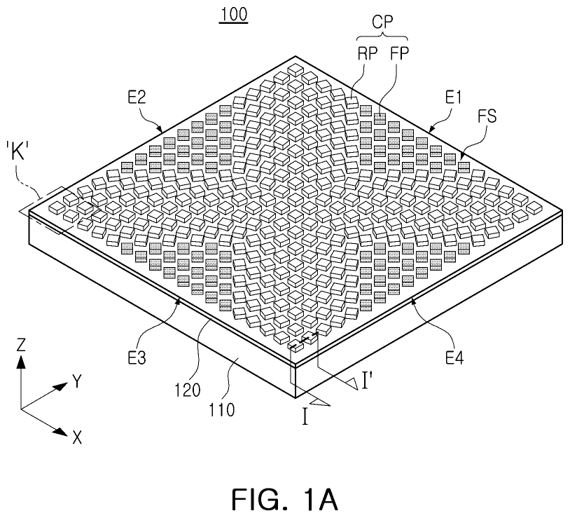

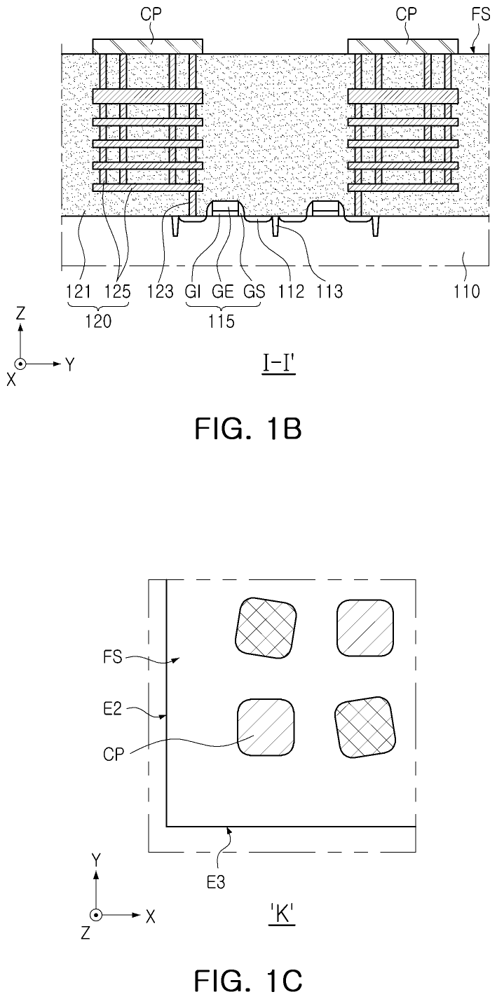

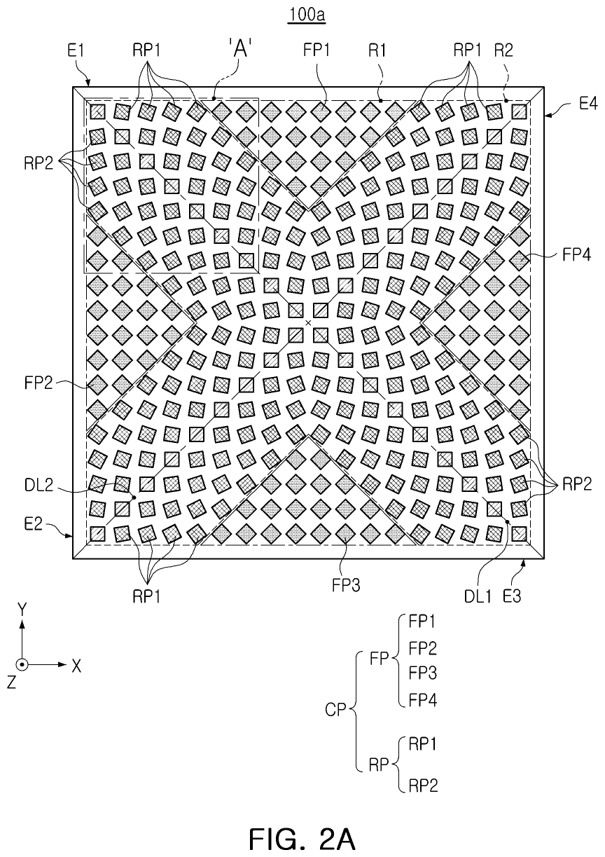

FIG. 1A is a perspective view of a semiconductor device 100 according to an example embodiment, and FIG. 1B is a cross-sectional view taken along line I-I′ of FIG. 1A.

Referring to FIGS. 1A and 1B, the semiconductor device 100 of the example embodiment may be a semiconductor chip including a semiconductor substrate 110, a circuit layer 120 on which an integrated circuit is formed, and a plurality of connection pads CP. The semiconductor device 100 may include, for example, a processor chip such as a central processing unit (CPU), a graphics processing unit (GPU), a field programmable gate array (FPGA), a digital signal processor, a cryptographic processor, a microprocessor, and a microcontroller. The semiconductor device 100 may be or include a logic chip such as an analog-to-digital converter, and an application-specific IC (ASIC). The semiconductor device 100 may be or include a memory chip such as a volatile memory such as dynamic RAM (DRAM), static RAM (SRAM), and the like, and a non-volatile memory such as phase change RAM (PRAM), magnetic RAM (MRAM), Resistive RAM (RRAM), flash memory, and the like.

The semiconductor substrate 110 may be a semiconductor wafer, or may be formed by separating a semiconductor wafer into a plurality of chips. The semiconductor substrate 110 may include, for example, a semiconductor element such as silicon or germanium, or a compound semiconductor such as silicon carbide (SiC), gallium arsenide (GaAs), indium arsenide (InAs), and indium phosphide (InP). The semiconductor substrate 110 may include a conductive region 112 and an isolation region 113 formed on one surface thereof. The conductive region 112 may be, for example, a structure doped with impurities such as a well and a source/drain. The isolation region 113 may be a device isolation structure having a shallow trench isolation(STI) structure, and may include a silicon oxide. A bottom surface of the semiconductor substrate 110, not illustrated in the drawings, may be covered with an insulating film made of a silicon oxide film, a silicon nitride film, a polymer, or a combination thereof.

The semiconductor substrate 110 may include a plurality of discrete devices. The plurality of discrete devices may be active and/or passive devices. The discrete device may be, for example, FETs (field effect transistors) such as planar FET, FinFET, and the like. The FETs may include the conductive region 112 of the semiconductor substrate 110. The plurality of discrete devices and electrical connection structures therebetween may constitute logic gates such as AND, OR, NOT, and the like. The logic gates may constitute an integrated circuit. The integrated circuit may be a memory device such as flash memory, DRAM, SRAM, EEPROM, PRAM, MRAM, FeRAM, RRAM, and the like. The integrated circuit may be system LSI, CIS, or MEMS. The discrete device (e.g., FET) may include a gate structure 115. The gate structure 115 may include a gate insulating layer GI, a gate electrode GE disposed on the gate insulating layer GI, and a gate spacer GS surrounding the gate insulating layer GI and the gate electrode GE. The gate insulating layer GI may include a silicon oxide or a silicon nitride. The gate electrode GE may include a semiconductor material, a metal material, or the like. The gate spacer GS may be formed of a silicon oxide layer, a silicon nitride layer, a silicon carbide layer, or a combination thereof.

The circuit layer 120 may be disposed on one surface of the semiconductor substrate 110 on which the conductive region 112 is formed. The circuit layer 120 may include an interlayer insulating layer 121 and an interconnection structure 125. The interlayer insulating layer 121 may be formed to cover the discrete devices and the interconnection structure 125. A portion of the interconnection structure 125 may be electrically separated or isolated from a portion of the discrete devices disposed on the semiconductor substrate 110. The interlayer insulating layer 121 may include Flowable Oxide (FOX), Tonen SilaZen(TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the interlayer insulating layer 121 surrounding the interconnection structure 125 may be formed of a low-k dielectric layer. The interlayer insulating layer 121 may be formed using a chemical vapor deposition(CVD) process, a flowable-CVD process, or a spin coating process.

The interconnection structure 125 may be formed in a multilayer structure including a plurality of interconnection patterns and a plurality of vias. The plurality of interconnection patterns and the plurality of vias may include or be formed of, for example, aluminum (Al), gold (Au), cobalt (Co), copper (Cu), nickel (Ni), lead (Pb), tantalum (Ta), tellurium (Te), titanium (Ti), tungsten(W), or a combination thereof. A barrier layer (not shown) including titanium (Ti), a titanium nitride (TiN), tantalum (Ta), or a tantalum nitride (TaN) may be disposed between the interconnection patterns and the interlayer insulating layer 121 and/or between the vias and the interlayer insulating layer 121. The interconnection structure 125 may be electrically connected to the discrete devices by a via 123 (e.g., a contact plug).

The plurality of connection pads CP may be electrically connected to the interconnection structure 125. The interconnection structure may electrically connect at least some of the plurality of conductive pads to the discrete devices. The plurality of connection pads CP may include an electrically and/or thermally conductive material. The plurality of connection pads CP may include, for example, aluminum (Al) or an aluminum (Al) alloy, but the present inventive concept is not limited thereto. According to an example embodiment, the semiconductor device 100 may further include a passivation layer covering the plurality of connection pads CP. The passivation layer may include at least one of silicon oxide and silicon nitride.

In example embodiments, the plurality of connection pads CP may be connected to internal wiring (e.g., the interconnection structure 125) of the device, and may transmit signals and/or supply voltages from an external source to an internal wiring and/or internal circuit of the device. For example, the connection pads CP may electrically connect an integrated circuit of the semiconductor device and another device. The connection pads CP may transmit supply voltages and/or signals between an integrated circuit of the semiconductor device and another device to which the semiconductor chip is connected.

The connection pads CP may be provided on or near an external surface of the semiconductor device and may have a planar surface having dimensions greater than those of the interconnection structure 125 (e.g., X-Y horizontal dimensions of a pad CP are both greater than the width of the interconnection structure 125) to promote an electrical connection to a terminal, such as a bump, solder ball, a bonding wire and an external wiring.

The plurality of connection pads CP may be described as a plurality of conductive pads.

The plurality of conductive pads CP may be or include dummy pads as well as normal pads. The dummy pads may not have any electrical connection to any of the integrated circuits of the semiconductor device 100. However, the dummy pads may have the same or similar structure and/or shape as normal pads of the semiconductor device 100, including being formed of the same material (e.g., formed of the same material layer at the same level). The dummy pads may not be used to convey signals or power (unlike normal pads which are connected to the internal circuitry of the semiconductor device to communicate signals and/or power). In some instances, the dummy pads may form all or part of an electrical node that is electrically floated (e.g., not electrically) connected to any other conductor). The dummy pads (along with the normal pads) may be elements of the uppermost conductive layer (e.g., metal layer) of the semiconductor device 100. In some exemplary embodiments, the dummy pads and the normal pads may be covered by a passivation layer that is then patterned to expose the dummy pads and the normal pads.

In some embodiments, at least part of the dummy pads may act as thermal pads. The thermal pads and/or the interconnection structure 125 may be thermally conductive to transfer heat from the semiconductor device 100 to an external configuration(e.g., heat sink). Accordingly, the thermal pad may decrease the operating temperature of the semiconductor device 100 by transferring heat to an external board, a package, a heat sink, or the like.

In exemplary embodiments, the plurality of connection pads CP may have a predetermined shape, and may be arranged in a predetermined manner on a front surface FS defined by the edges E1, E2, E3, and E4 of the semiconductor device 100.

The edges E1, E2, E3, and E4 may be edges of the circuit layer 120, and they may be described as circuit edges. The circuit layer 120 may be described as having the front surface FS defined by the circuit edges E1, E2, E3, and E4. The front surface FS may be described as including front surface vertices. Each pair of the circuit edges may share one of the front surface vertices. The front surface FS may be described as including a front surface diagonal which is a line segment joining a predetermined pair of the front surface vertices. A line segment, as described herein, refers to a physical or conceptual straight line extending between two points.

The plurality of connection pads CP may include first connection pads FP (which may be referred to as ‘reference pads’ herein), and second connection pads RP (which may be referred to as ‘rotated pads’ herein).

Each of the first connection pads (reference pads) FP may have a reference pad surface in a plan view (as viewed from Z-direction), and reference pad edges may define the reference pad surface. Each pair of the reference pad edges may share one of reference pad vertices. The reference pads FP may have a reference pad diagonal which is a line segment joining a predetermined pair of the reference pad vertices.

Each of the second connection pads (rotated pads) RP may have a rotated pad surface in a plan view (as viewed from Z-direction), and rotated pad edges may define the rotated pad surface. Each pair of the rotated pad edges may share one of rotated pad vertices. The rotated pads RP may have a rotated pad diagonal which is a line segment joining a predetermined pair of the rotated pad vertices.

The diagonal of a set of the first connection pads FP (reference pad vertices) may be aligned toward the edges E1, E2, E3, and E4, and the diagonal of a set of the second connection pads RP (rotated pad vertices) may be aligned toward a corner portion in which the edges E1, E2, E3, and E4 meet each other. The plurality of connection pads CP are arranged so that a portion overlapping with the peeling boundary of the dicing tape is minimized, thereby facilitating peeling of the dicing tape and improving process efficiency.

FIG. 1C is a plan view of the semiconductor device 100 illustrated in FIGS. 1A and 1B. FIG. 1C is a partially enlarged view of region ‘K’ of FIG. 1A

Referring to FIG. 1C, the vertices of the connection pads RP may be rounded corners of polygon-shaped pads in a plan view. For example, the vertices of the connection pads RP may be rounded corners of square-shaped pads in a plan view as shown in FIG. 1C. The rounded vertices may unintentionally result from acceptable variations that may occur due to conventional manufacturing processes.

As described previously, terms as used herein when describing features of orientation, layout, location, shapes, sizes, compositions, amounts, or other measures do not necessarily mean features defined by the dictionary meaning of the terms, but are intended to encompass acceptable variations that may occur, for example, due to manufacturing processes or to encompass typically acceptable tolerances of conventional manufacturing process technology. For example, “square” may encompass a square having rounded vertices as a typically acceptable variation in industry. The term “substantially” may be used herein to emphasize this meaning. In this context, terms such as “polygonal,” “same,” “equal,” “planar,” “coplanar,” “parallel,” “orthogonal,” “perpendicular,” “linearly,” “center,” “symmetrical,” “coincide,” “align,” “passing through,” and “aligned” as used herein may encompass such variations or tolerances that may be resulted from conventional manufacturing processes.

Hereinafter, the arrangement of the plurality of connection pads CP will be described in more detail with reference to the drawings.

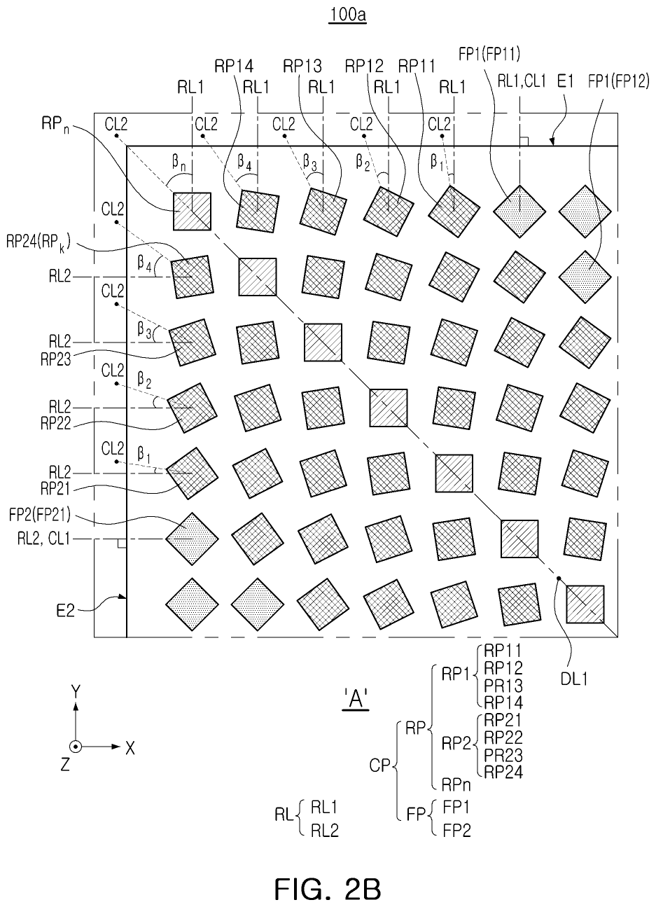

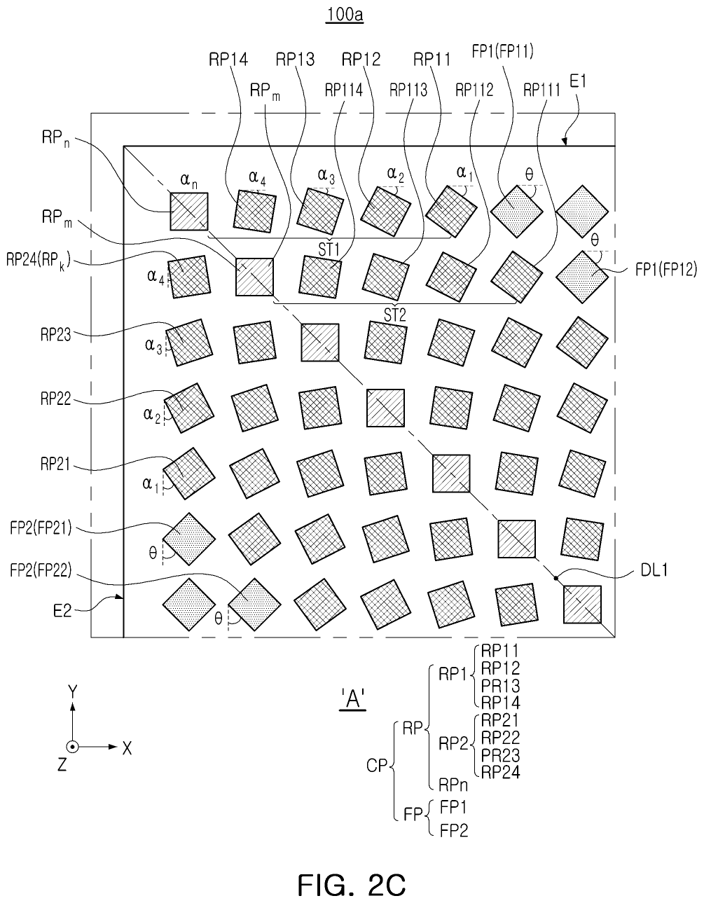

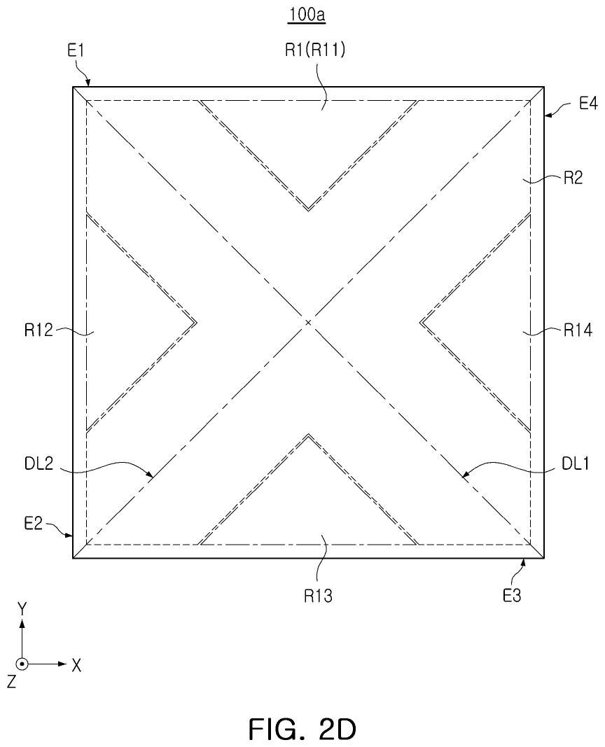

FIG. 2A is a plan view of a semiconductor device 100a according to an example embodiment, FIGS. 2B and 2C are partially enlarged views of region ‘A’ of FIG. 2A, and FIG. 2D is a plan view illustrating first and second regions.

Referring to FIGS. 2A and 2D, the semiconductor device 100a of an example embodiment may include a plurality of connection pads CP having a polygonal planar shape and edges E1, E2, E3, and E4 defining a front surface of the circuit layer 120 (shown in FIG. 1B) on which the plurality of connection pads CP are disposed. For example, the semiconductor device 100a may have a plane (front surface) defined by the first edge E1, the second edge E2, the third edge E3, and the fourth edge E4. In the example embodiment, the front surface of the semiconductor device 100a is shown as a square shape in a plan view, but the present inventive concept is not limited thereto.

The plurality of connection pads CP may have a polygonal planar shape. For example, the plurality of connection pads CP may have a regular polygonal shape such as a square, regular hexagon, or regular octagon in a plan view, but the present inventive concept is not limited thereto.

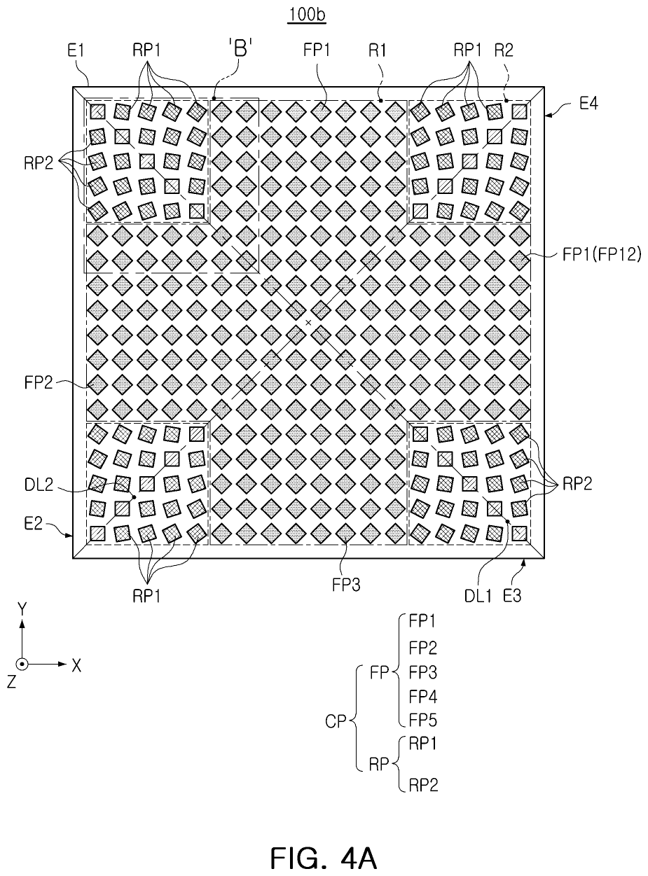

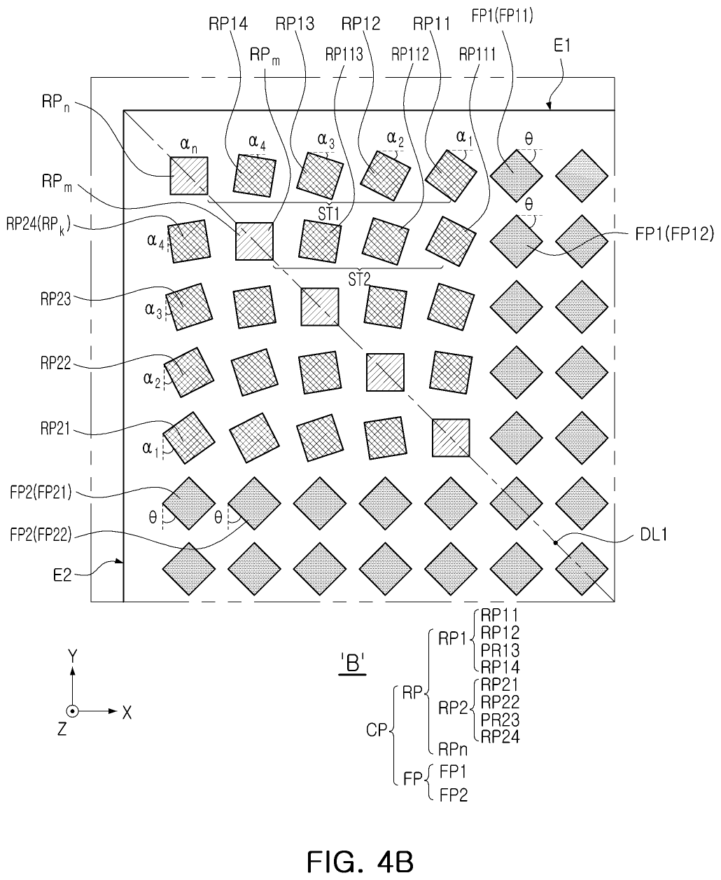

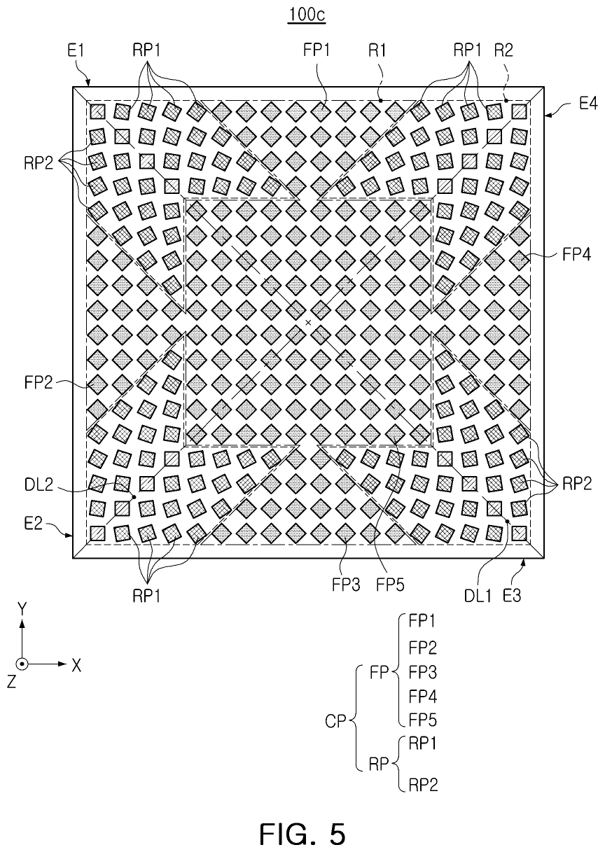

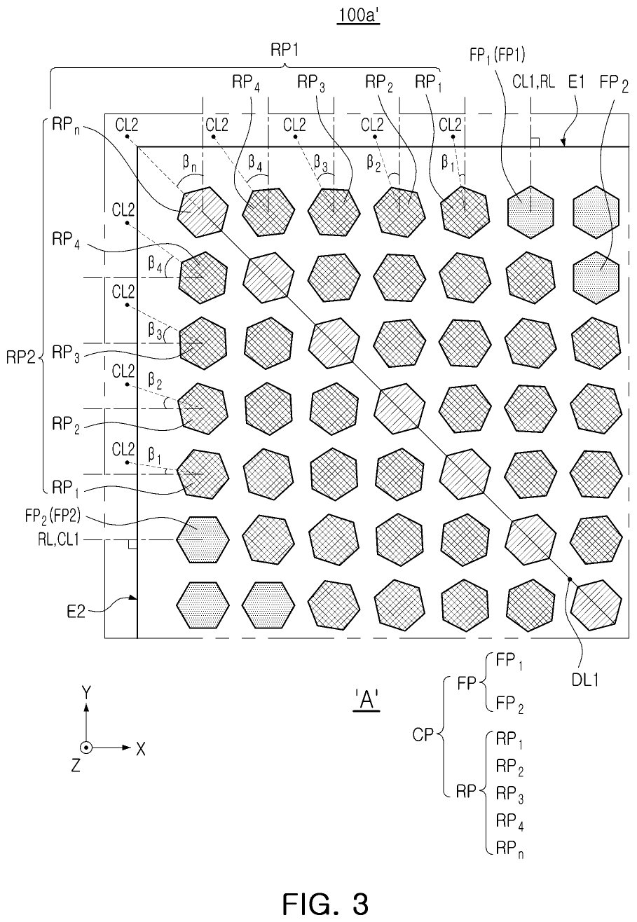

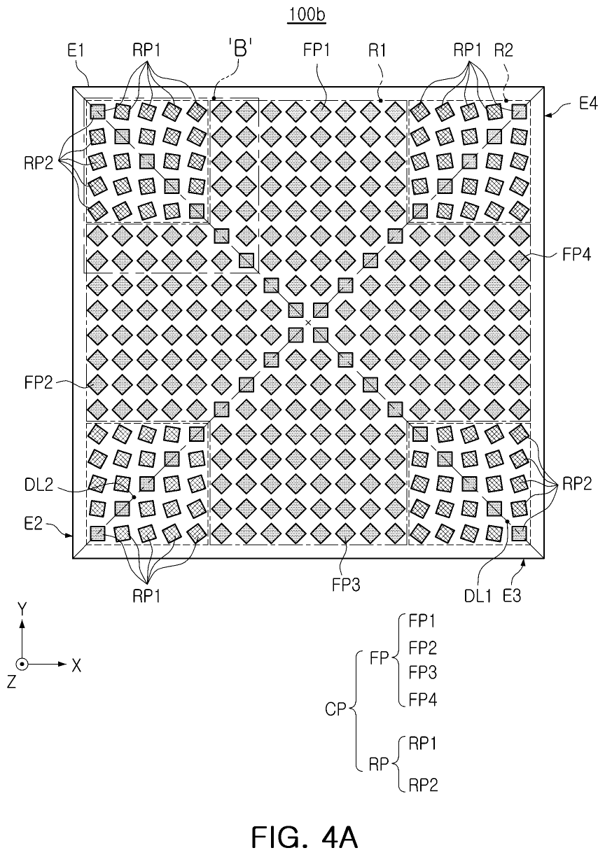

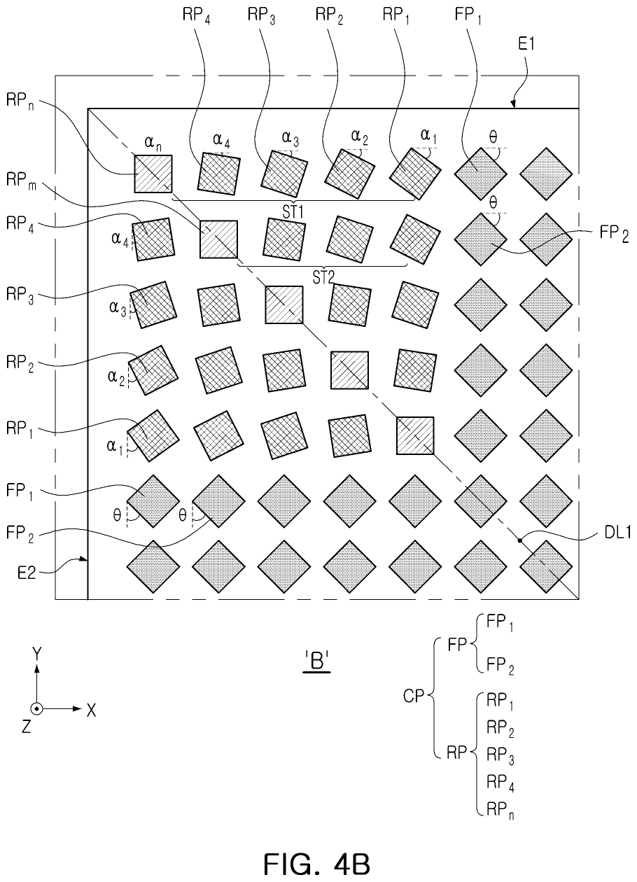

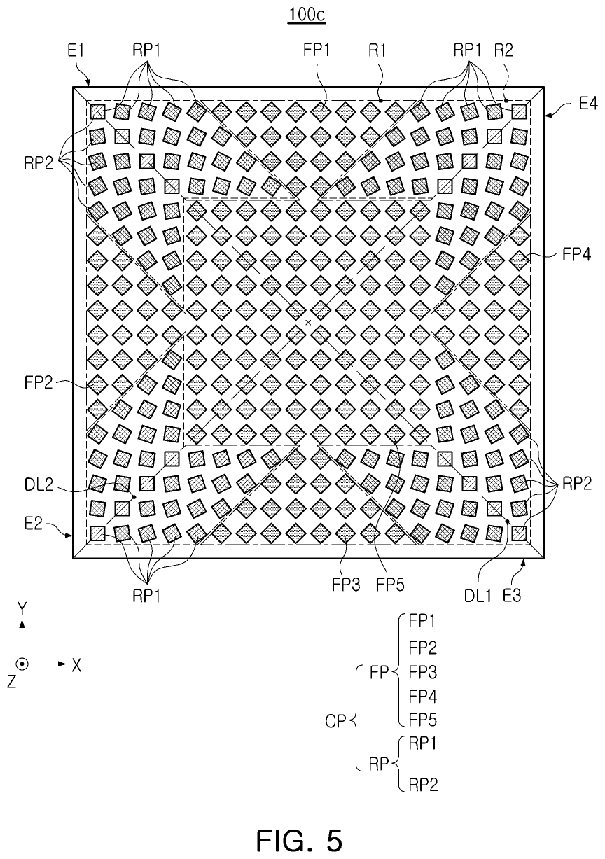

The plurality of connection pads CP may include reference pads FP disposed within four of first regions R1 adjacent to the center of each of the four edges E1, E2, E3, and E4, and rotated pads RP disposed within a second region R2 occupying the corner of each of the edges E1, E2, E3, and E4. The second region R2 may occupy corner portions (e.g., portions adjacent to the circuit vertices) and a center portion of the front surface of the semiconductor device 100a. The second region R2 may occupy an X shaped area around the circuit diagonal lines (also referred to as circuit diagonals) DL1 and DL2 crossing the front surface of the semiconductor device 100a. For example, the second region R2 may be formed in an X shape crossing the front surface of the semiconductor device 100a, but the present inventive concept is not limited thereto (e.g., the example embodiments in FIGS. 4A and 5).

The reference pads FP may include a first group of reference pads FP1 adjacent to the first circuit edge E1, a second group of reference pads FP2 adjacent to the second circuit edge E2, and a third group of reference pads FP3 adjacent to the third circuit edge E3, and a fourth group of reference pads FP4 adjacent to the fourth circuit edge E4. Each of the reference pads FP may be disposed so that a reference pad diagonal is orthogonal to the corresponding edges E1, E2, E3, and E4. The first to fourth groups FP1 to FP4 of reference pads may be located in the first regions R11 to R14, respectively.

The rotated pads RP may include a first group of rotated pads RP1 arranged in a series extending in a horizontal direction(X-direction) and a second group of rotated pads RP2 arranged in a series extending in a vertical direction(Y-direction). When viewed in a plan view, an up/down direction may be referred to as a vertical direction(Y-direction) and a left/right direction may be referred to as a horizontal direction. However, when viewed in a cross-section from one of the X-direction and Y-direction, a vertical direction refers to the Z-direction. The rotated pads RP may include a third group of rotated pads which are disposed on the circuit diagonals DL1 and DL2.

Each rotating pad RP may have a shape that is rotated in a plan view by a certain angle in a particular direction relative to the shape of at least one of the plurality of reference pads FP. Each of the rotated pads RP may have a shape that is rotated so that a rotated pad diagonal has a predetermined angle with respect to a reference line orthogonal to the corresponding edges E1, E2, E3, and E4. The rotated pads RP may be disposed substantially symmetrically with respect to the diagonal lines DL1 and DL2.

The rotated pads RP may have a shape that is rotated in a direction toward a central portion of the edges E1, E2, E3, and E4. For example, referring to FIGS. 2B and 2C, in the region ‘A’ of FIG. 2A, the planar shape of each of the first group of rotated pads RP1 may have a shape that is rotated in a direction(e.g., clockwise), when compared to a rotated pad RPn which is located on the corner portion of the front surface and disposed on the diagonal lines DL1. The planar shape of each of the second group of rotated pads RP2 may be rotated in another direction(e.g., counterclockwise), when compared to the rotated pad RPn (also described as outermost rotated pad). As the rotated pads RP get closer to the front surface diagonal DL1 (or the outermost rotated pad RPn), the degree of rotation may increase.

Hereinafter, referring to FIGS. 2B and 2C, a disposition of the reference pads FP and rotated pads RP will be described in more detail. The disposition of the reference pads FP and rotated pads RP, to be described later, has been described based on some regions (‘A’ regions) on the plane, but may be understood to be equally applied to other regions (regions other than ‘A’) not illustrated in FIGS. 2B and 2C.

In FIG. 2B, reference lines RL are illustrated. The reference lines RL include first reference lines RL1 and first reference lines RL2. The first reference lines RL1 are parallel to the second edge E2. The second reference lines RL2 are parallel to the first edge E1. Referring to FIG. 2B, a first center line CL1 of each of the reference pads FP, passing through a predetermined pair of vertices of a planar shape may be disposed to coincide (align) with a corresponding one of reference lines RL. Each of the reference lines RL may pass through each center of the planar shape of the reference pad surfaces, and may be orthogonal to the adjacent one of the edges (e.g., E1 or E2 in FIG. 2B). The first center line CL1 may be described as a first reference pad diagonal which is a line segment joining a predetermined pair of the reference pad vertices of each of the reference pads FP.

The first center line CL1 of a first reference pad FP11 adjacent to the first edge E1 may be orthogonal to the first edge E1. The first center line CL1 of a second reference pad FP21 adjacent to the second edge E2 may be orthogonal to the second edge E2. The first center lines CL1 of the reference pads FP may be parallel to a predetermined one of the circuit edges. For example, the first center lines CL1 of the first group of reference pads FP1 may be parallel to the circuit edge E2. The first center lines CL1 of the second group of reference pads FP2 may be parallel to the circuit edge E1.

Second center lines CL2 may coincide (align) with corresponding rotated pad diagonals of the rotated pads RP. Each of the second center lines CL2 of the first group of rotated pads RP1 may be arranged to have a counterclockwise angle with respect to each first reference line RL1, while each of the second center lines CL2 of the second group of rotated pads RP2 may be arranged to have a clockwise angle with respect to each first reference line RL2. For example, each of the second center lines CL2 of the first group of rotated pads RP1 may extend in a virtual line rotated counterclockwise with respect to the first reference line RL1, and each of the second center lines CL2 of the second group of rotated pads RP2 may extend in a virtual line rotated clockwise with respect to the second reference line RL2.

The rotated pads RP11, RP12, RP13 and RP14 of the first group of rotated pads RP1 may be arranged symmetrically to the rotated pads RP21, RP22, RP23 and RP24 of the second group of rotated pads RP2 with respect to the first front surface diagonal DL1 in a plan view.

A first rotated pad set may include first to n^{th} rotated pads (RP11, RP12, RP13 RP14, . . . . RPₙ) sequentially disposed in a series (and/or linearly) from one side of one of the reference pads FP11. The rotated pad RP14 may be described as a n−1th rotated pad. Each of the rotated pads RP may be disposed so that the second center line CL2 has a rotation angle βₙ according to the following [Equation 1] with reference to the reference line RL.

$${β}_{n} = n ( 45 ° / N ) \qquad [ Equation 1 ]$$

In the [Equation 1], n represents an arrangement order of the first to n^{th} rotated pads, and N is the number (e.g., 5) of the first to n^{th} rotated pads.

For example, when the number of rotated pads RP is five, a rotation angle β₁ of the first rotated pad RP11 may be about 9°, a rotation angle β₂ of the second rotated pad RP12 may be about 18°, a rotation angle β₃ of the third rotated pad RP13 may be about 27°, a rotation angle β₄ of the fourth rotated pad RP14 may be about 36°, and a rotation angle βₙ of the fifth rotated pad RPₙ(n=5) may be about 45°.

The rotation angle may be within a range allowing an acceptable process tolerance (e.g., ±5° of the rotation angle βₙ according to the following [Equation 1]). For example, each second center line CL2 of the first to n^{th} rotated pads may be within a range from (βn−5°) to (βₙ+5°). In this regard, the term “substantially” or “about” may be used to encompass acceptable process tolerance (or variation).

The first rotated pad set may be disposed in a straight line on one side of a corresponding reference pad. For example, the first to n^{th} rotated pads (RP11, RP12, RP13 RP14, . . . . RPₙ) may be aligned in one direction extending from one side of the corresponding reference pad FP11. For example, the first reference pad FP11 may be adjacent to the first circuit edge E1 in a first direction (e.g., Y-direction), and the first to n^{th} rotated pads (RP11, RP12, RP13, RP14, . . . . RPₙ) may be aligned with the first reference pad FP11 in a second direction(e.g., X-direction) perpendicular to the first direction(e.g., Y-direction). The n^{th} rotated pad RPₙ disposed furthest from the corresponding reference pad FP11 may be located on the diagonal line DL1 (or DL2) connecting the vertices of the circuit edges. For example, the second center line CL2 of the n^{th} rotated pad RPₙ may coincide with the first diagonal line DL1 (the front surface diagonal may substantially coincide with the rotated pad diagonal of the n^{th} rotated pad).

The rotated pads RP may further include a second rotated pad set (RP21, RP22, RP23, RP24). The rotated pads RP21, RP22, RP23, RP24 may be described as first to k^{th} rotated pads of a second rotated pad set, and the k^{th} rotated pad may be the rotated pad RP24. The second set of reference pads may be adjacent to the second edge E2 in the second direction(e.g., X-direction). The first to k^{th} rotated pads RP21, RP22, RP23, RP24 of the second rotated pad set may be aligned in series in the first direction(e.g., Y-direction) on(or from) one side of the reference pads FP21.

The first to k^{th} rotated pads of the second rotated pad set may extend in a straight line from one side of the n^{th} rotated pad of the first rotated pad set toward the second reference pad FP21. The number pads of the first rotated pad set may be 1 greater than the number of pads of the second rotated pad set (the number n may be 1 greater than the number k). The rotated pads RP may be disposed such that an extension line of the first to n^{th} rotated pads (RP11, RP12, RP13 RP14, . . . RPₙ) of the first rotated pad set may intersect an extension line of the first to k^{th} rotated pads of a second rotated pad set. For example, an extension line of the series of rotated pads (RP11, RP12, RP13, RP14, RPₙ) adjacent to the first edge E1 may orthogonally intersect an extension of the series of rotated pads adjacent to the first edge E2 (RP21, RP22, RP23, RP24). The first to n^{th} rotated pads may be disposed along and parallel to the first edge E1.

The first to n−1^{th} rotated pads of the first rotated pad set may be disposed substantially symmetrically to the first to k^{th} rotated pads of a second rotated pad set with respect to the diagonal line DL1, and the n^{th} rotated pad may be disposed on the diagonal line DL1.

In some embodiments, all of the conductive pads CP formed on the circuit layer 120 may be disposed such that one or more features thereof (e.g., the number of pads, the shape of the pads, the rotation angle of the pads and/or the size of the pads) are substantially symmetrical, in a plan view, with respect to the first diagonal line DL1, the second diagonal line DL2 and/or the center point of the front surface.

Referring to FIG. 2C, the reference pads FP may be disposed so that at least one edge of each of the reference pads FP has a reference angle θ according to the following [Equation 2] with respect to the adjacent edges E1 or E2.

$$θ = 180 ° / z \qquad [ Equation 2 ]$$

In the [Equation 2], z represents the number of sides of the polygonal plane shape.

The reference angle θ may be within a range allowing an acceptable process tolerance (e.g., ±5° of the rotation angle θ according to the [Equation 2]). For example, each reference angle θ of the reference pads may be within a range from (θ−5°) to (θ+5°). In this regard, the term “substantially” may be used to encompass acceptable process tolerance (or variation).

For example, when the planar shape of the reference pads FP is square, the reference angle θ may be about 45° (preferably within a range of 40° to 50°).

A predetermined one of the rotated pad edges of each rotated pads RP has an inclination angle αₙ with respect to the predetermined one of the circuit edges. The rotated pads RP may be disposed so that the inclination angles αₙ smaller than the reference angle θ of the reference pads FP. For example, the predetermined one of the circuit edges may be edge E1 or E2. The inclination angles αₙ of the rotated pads RP may become relatively smaller as it approaches the corresponding diagonal line DL1 or DL2. As the rotated pads get closer to the front surface diagonal, the inclination angles αₙ of the rotated pads may decrease. The inclination angle αₙ may be defined by the following [Equation 3]. For example, the rotated pads RP sequentially arranged from one side of the reference pad FP to the corresponding diagonal line DL1. Each of the first to n^{th} rotated pads (RP11, RP12, RP12, RP14, . . . . RPₙ) may have an inclination angle αₙ substantially according to the following [Equation 3], n represents an arrangement order of the first to n^{th} rotated pads, and N is the number of the first to n^{th} rotated pads.

$${α}_{n} = 45 ° - n ( 45 ° / N ) \qquad [ Equation 3 ]$$

For example, when the number N of rotated pads RP is 5, an inclination angle α₁ of the first rotated pad RP11 may be about 36°, an inclination angle α₂ of the second rotated pad RP12 may be about 27°, an inclination angle α₃ of the third rotated pad RP13 may be about 18°, an inclination angle α₄ of the fourth rotated pad RP14 may be about 9°, and an inclination angle αₙ of the fifth rotated pad RPₙ(n=5) may be about 0°. The n^{th} rotated pad RPₙ(which is disposed furthest from the corresponding reference pad FP and/or is located on the diagonal lines DL1 or DL2 of the semiconductor device 100a) may be disposed so that one rotated pad edge thereof is parallel to the adjacent edges E1 or E2.

The rotated pad RP may further include a third rotated pad set The second rotated pad set ST2 may include first to m^{th} rotated pads (RP111, RP112, RP113, RP114, . . . RPₘ). The third rotated pad set may be arranged in a second direction(e.g., X-direction) from one side of another first reference pad FP12. The first reference pads FP11 and FP12 may be spaced apart by different distances from the corresponding edge (also described as predetermined circuit edge, e.g., E1). For example, the first reference pad FP11 may be spaced apart from the first edge E1 by a first distance in a first direction(e.g., Y-direction). The first reference pad FP12 may be spaced apart from the first edge E1 by a second distance greater than the first distance in the first direction(e.g., Y-direction). The first rotated pad set may include first to n^{th} rotated pads (RP1, RP2, RP3, RP4, . . . . RPₙ) sequentially arranged in a second direction(e.g., X-direction) on(or from) one side of the first reference pad FP11. The second rotated pad set ST2 may include first to m^{th} rotated pads (RP111, RP112, RP113, RP114, . . . . RPₘ) sequentially arranged in a second direction(e.g., X-direction) on(or from) one side of the first reference pad FP12. The n^{th} rotated pad RPₙ and the m^{th} rotated pad RPₘ may be disposed on the first diagonal line DL1. The first rotated pad set and second rotated pad set may include the same number of rotated pads RP (e.g., n=m). In this case, the first reference pads FP11 and FP12 may overlap (be disposed on) a line parallel to the first diagonal line DL1.

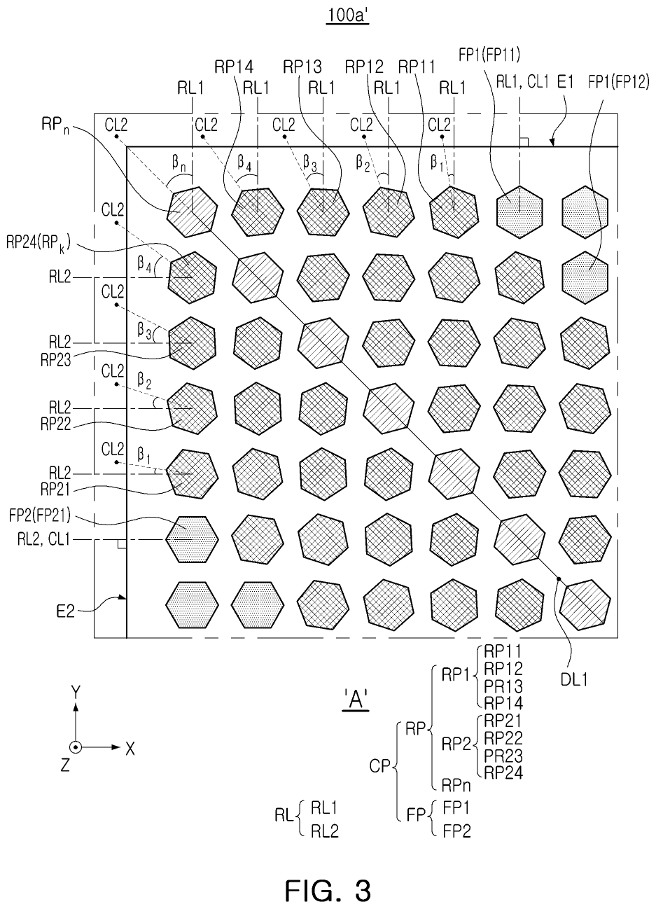

FIG. 3 is a partially enlarged view for illustrating a semiconductor package 100a′ of a modified example. FIG. 3 is for illustrating a region ‘A ’of the modified example, and is equivalent to the partially enlarged view of the region ‘A’ of FIG. 2A.

Referring to FIG. 3, in the semiconductor package 100a′ of the modified example, the disposition of the reference pads FP and the rotated pads RP may be the same as or similar to the disposition described with reference to FIGS. 1A to 2C, except that a planar shape of the plurality of connection pads CP is a regular hexagon in FIG. 3.

The reference pads FP may be disposed so that each first center line CL1 thereof, passing through a vertex of a planar shape, substantially coincides with a corresponding one of reference lines RL. The reference lines RL may pass through each center of the planar shape of the reference pad surfaces, and may be orthogonal to the adjacent one of the edges E1 or E2. The first center line CL1 of the first reference pad FP11 adjacent to the first edge E1 may be orthogonal to the first edge E1. The first center line CL1 may be described as a first reference pad diagonal which is a line segment joining a predetermined pair of the reference pad vertices of each of the reference pads FP. The first center line CL1 of the second reference pad FP21 adjacent to the second edge E2 may be orthogonal to the second edge E2.

Each rotating pad RP may have a shape, in a plan view, that is rotated by a certain angle in a particular direction relative to the shape of at least one of the plurality of reference pads FP. For example, each of the second center line CL2 (a rotated pad diagonal which is a line segment joining a predetermined pair of the rotated pad vertices of the each of the rotated pads RP) may extend along a line having an angle with respect to a corresponding one of the reference lines RL. The second center line CL2 of each of the first group of rotated pads RP1 may be disposed on a virtual line rotated counterclockwise with respect to the reference line RL1, and the second center line CL2 of each of the second group of rotated pads PR2 may be disposed on a virtual line rotated clockwise with respect to the reference line RL2.

Similar to the embodiment previously described, the conductive pads CP may be disposed such that one or more features thereof (e.g., the number of pads, the shape of the pads, the rotation angle of the pads and/or the size of the pads) are substantially symmetrical, in a plan view, with respect to the first diagonal line DL1, the second diagonal line DL2 and/or the center point of the front surface.

A first rotated pad set may include first to n^{th} rotated pads (RP11, RP12, RP13 RP14, . . . RPₙ) sequentially disposed in a straight line from one side of the reference pads FP11. Each of the rotated pads RP may be disposed so that the second center line CL2 passing through a vertex of the planar shape has a rotation angle βₙ according to the [Equation 1] above with reference to the reference line RL.

For example, when the number N of rotated pads RP is 5, a rotation angle β₁ of the first rotated pad RP11 may be about 9°, a rotation angle β₂ of the second rotated pad RP12 may be about 18°, a rotation angle β₃ of the third rotated pad RP13 may be about 27°, a rotation angle β4 of the fourth rotated pad RP14 may be about 36°, and a rotation angle βₙ of the fifth rotated pad RPₙ may be about 45° (n=5). The rotation angle may be within a range allowing an acceptable process tolerance (e.g., ±5% of the rotation angle βₙ according to the [Equation 1]).

The first rotated pad set (the first to n^{th} rotated pads) may be aligned in a series on one side of the corresponding reference pad FP. For example, the first to n^{th} rotated pads (RP11, RP12, RP13 RP14, . . . . RPₙ) may be aligned in one direction extending from one side of the corresponding reference pad FP11. For example, the first reference pad FP11 may be adjacent to the first edge E1 in a first direction(e.g., Y-direction), and the first to n^{th} rotated pads (RP11, RP12, RP13, RP14, RPₙ) may be aligned with the first reference pad FP11 in a second direction(e.g., X-direction) perpendicular to the first direction(e.g., Y-direction). The second center line CL2 of the n^{th} rotated pad RPₙ may substantially coincide with (be disposed on) the first diagonal line DL1.

The rotated pads RP may further include a second rotated pad set (RP21, RP22, RP23, RP24). The rotated pads RP21, RP22, RP23, RP24 may be described as first to k^{th} rotated pads of a second rotated pad set, and the k^{th} rotated pad may be the rotated pad RP24. The second set of reference pads may be adjacent to the second edge E2 in the second direction(e.g., X-direction). The first to k^{th} rotated pads RP21, RP22, RP23, RP24 of the second rotated pad set may be aligned in a series in the first direction(e.g., Y-direction) from one side of the reference pads FP21.

The first to k^{th} rotated pads of the second rotated pad set may extend in a straight line from one side of the n^{th} rotated pad of the first rotated pad set toward the second reference pad FP21. The number pads of the first rotated pad set may be 1 greater than the number of pads of the second rotated pad set. For example, the number n may be 1 greater than the number k. The rotated pads RP may be disposed such that an extension line of the first to n^{th} rotated pads (RP11, RP12, RP13 RP14, . . . . RPₙ) of the first rotated pad set may intersect an extension line of the first to k^{th} rotated pads of a second rotated pad set. For example, an extension line of the series of rotated pads adjacent to the first edge E1 (RP11, RP12, RP13, RP14, RPₙ) may orthogonally intersect an extension of the series of rotated pads adjacent to the first edge E2 (RP21, RP22, RP23, RP24).

The first to n−1^{th} rotated pads of the first rotated pad set and the first to k^{th} rotated pads of a second rotated pad set may be disposed substantially symmetrically with respect to the diagonal line DL1, and the n^{th} rotated pad may be disposed on the diagonal line DL1.

FIG. 4A is a plan view of a semiconductor device 100b according to an example embodiment, and FIG. 4B is a partially enlarged view of region ‘B’ of FIG. 4A.

Referring to FIGS. 4A and 4B, in the semiconductor device 100b of the example embodiment, the disposition of the reference pads FP and rotated pads RP may be the same as or similar to that described with reference to FIGS. 1A to 3, except for the number of rotated pads RP disposed in a straight line on one side of each of the reference pads FP11, FP12, FP21 and FP22. The reference pads FP11, FP12 may be spaced apart by different distances from an edge (e.g., E1). The reference pads FP21, FP22 may be spaced apart by different distances from an edge (e.g., E2).

A first rotated pad set may include first to n^{th} rotated pads (RP11, RP12, RP13, RP14, . . . RPₙ) sequentially arranged in a straight line in a second direction(e.g., X-direction) on one side of the first reference pad FP11. A second rotated pad set may include first to m^{th} rotated pads (RP111, RP112, RP113, . . . . RPₘ) sequentially arranged in a straight line in a second direction(e.g., X-direction) on one side of the first reference pad FP12. The n^{th} rotated pad RPₙ and the m^{th} rotated pad RPₘ may be disposed on the first diagonal line DL1 (or the second diagonal line DL2 as shown in FIG. 4A).

The number (e.g., 4) of the first to m^{th} rotated pads (RP111, RP112, RP113, . . . . RPₘ) included in the second rotated pad set may be smaller than the number (e.g., 5) of the first to n^{th} rotated pads (RP11, RP12, RP13, RP14, . . . . RPₙ) (e.g., n>m). In this case, the first and second reference pads FP1 and FP2 may overlap (be disposed on) a line extending in a first direction(e.g., Y-direction).

The second region R2 may be disposed only in the corner portions of the semiconductor device 100a (but, may not be disposed in the center region of the semiconductor device 100a), when compared to the disposition of the rotated pads in FIGS. 2A and 4. For example, the second region R2 in which the rotated pads RP are disposed may be located only in the corner portion of the edges E1, E2, E3, and E4. The rotated pads may not be disposed on the first diagonal line DL1 and the second diagonal line DL2 in the first region R1.

In some modified embodiments, though not shown in the drawings, most of the second region R2 may be disposed in the corner portions of the semiconductor device 100a, when compared to the disposition of the rotated pads in FIG. 2A. The second region R2 may not be disposed throughout the center region of the semiconductor device 100a, but some of the rotated pads may be disposed on the first diagonal line DL1 and the second diagonal line DL2. The second region R2 in which the rotated pads RP are disposed may be located in the corner portion of the edges E1, E2, E3, and E4. The rotated pads disposed on the first diagonal line DL1 and the second diagonal line DL2 may be in the first region R1. The first region R1 may be formed in a cross shape crossing the front surface of the semiconductor device 100a in the horizontal and vertical directions in a plan view, but the present inventive concept is not limited thereto.

FIG. 5 is a plan view of a semiconductor device 100c according to an example embodiment.

Referring to FIG. 5, the semiconductor device 100c of the exemplary embodiment may be the same as or similar to that described with reference to FIGS. 1A to 4B except for the shape of a first region R1 and a second region R2. In the present embodiment, the number of rotated pads RP arranged in the horizontal and vertical directions may be the same, but the second region R2 in which the rotated pads RP are disposed may be located only in a corner portion of the edges E1, E2, E3, and E4. The first region R1 may be formed to extend from a center portion of the semiconductor device 100a toward a center portion of the edges E1, E2, E3, and E4. The reference pads FP may further include a fifth group of reference pads FP5 disposed in the center portion of the semiconductor device 100a.

For example, when comparing with the pad number (i.e., n, k and m) of the rotated pad sets in FIG. 2A, the corresponding configuration of the pad numbers is the same as that of FIG. 2A. For example, as shown in FIG. 5, the number n is 1 greater than the number k, and the number n is the same as the number of m. The second region R2 in which the rotated pads RP are disposed may be located only in a corner portion of the front surface defined by edges E1, E2, E3, and E4. When comparing with FIG. 2A, the first region R1 may further include a center portion of the front surface defined by the edges E1, E2, E3, and E4. The reference pads FP may further include a fifth group of reference pads FP5 disposed in the center portion of the semiconductor device 100a.

As described above, the shape of the first region R1 and the second region R2 (e.g., the manner of disposition of the reference pads FP and rotated pads RP) may be modified in various manners in consideration of a peeling boundary of a dicing tape which will be described later.

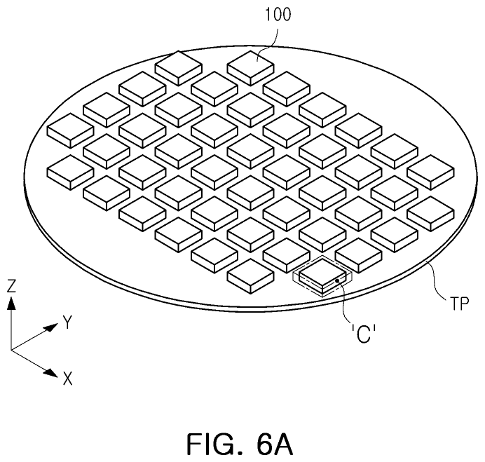

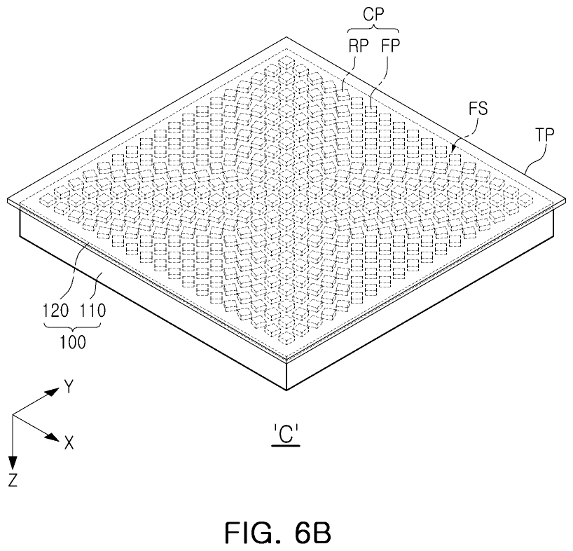

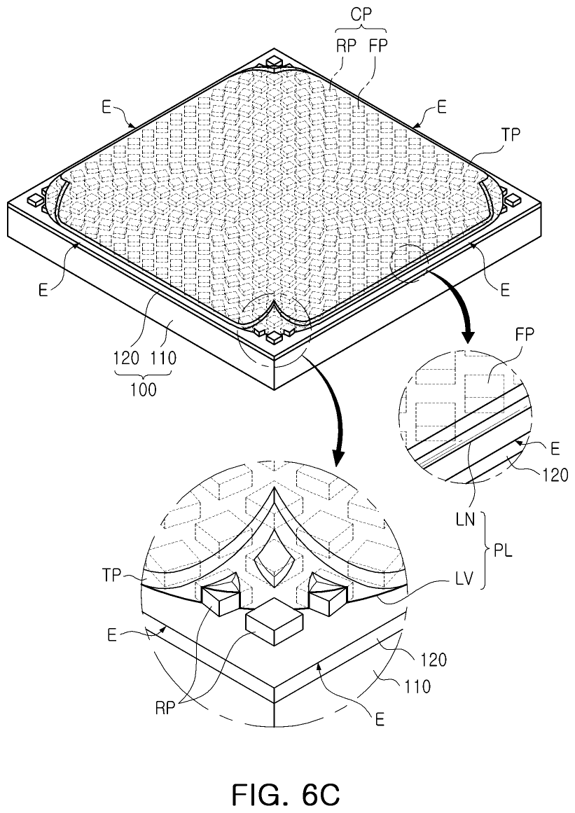

FIGS. 6A to 6C are diagrams for illustrating a peeling process of the dicing tape TP. FIG. 6B is a partially enlarged view illustrating the region ‘C’ of FIG. 6A, inverted upside down.

Referring to FIGS. 6A and 6B, a plurality of semiconductor devices 100 may be separated from a wafer by a dicing process. The plurality of semiconductor devices 100 may be disposed on a dicing tape TP. The dicing tape TP may be attached to a front surface FS of the plurality of semiconductor devices 100. The dicing tape TP may be supported by and fixed to, for example, a ring frame attached to a periphery of the dicing tape TP and/or the wafer. The semiconductor device 100 may be a semiconductor chip including a plurality of connection pads CP. The plurality of connection pads CP may be embedded in one surface of the dicing tape TP, or the plurality of connection pads CP may be covered by one surface of the dicing tape TP.

Referring to FIG. 6C, the semiconductor device 100 may be separated from the dicing tape TP. The semiconductor device 100 may be separated from the dicing tape TP using an eject unit and a pickup unit. The dicing tape TP may be peeled from the corners and the edges E of the semiconductor device 100 toward the center of the front surface. A peeling boundary PL of the dicing tape TP may include a straight portion LN adjacent to the center portion of the edges E and a curved portion LV adjacent to the corner portion. In an example embodiment, the reference pads FP may be disposed so that a contact area (also described as contact line) with the dicing tape TP is minimized in the straight portion LN of the peeling boundary PL. In addition, the rotated pads RP may be disposed so that the contact area with the dicing tape TP is minimized in the curved portion LV of the peeling boundary PL.

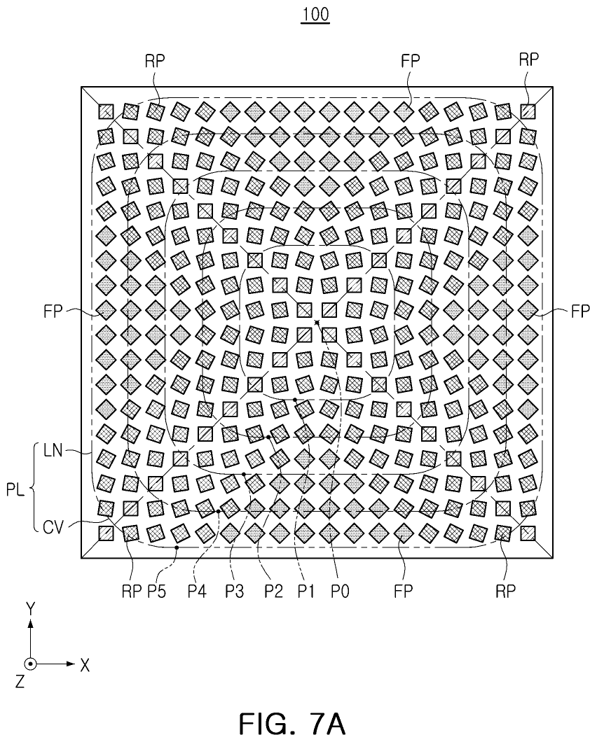

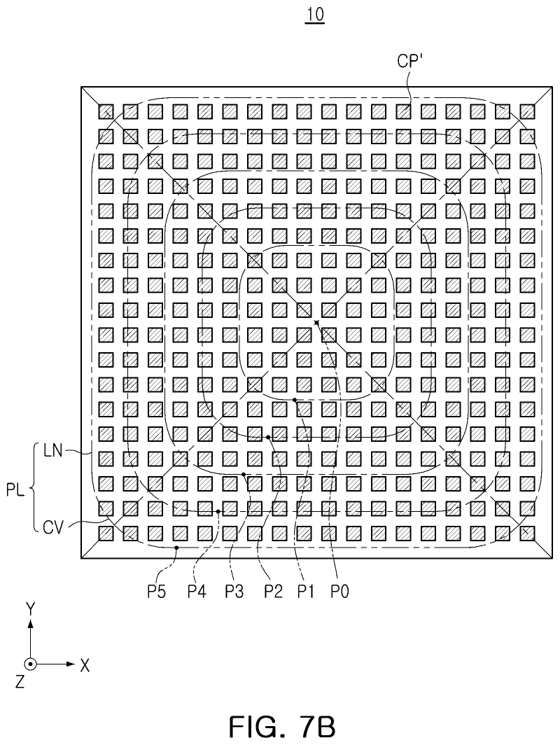

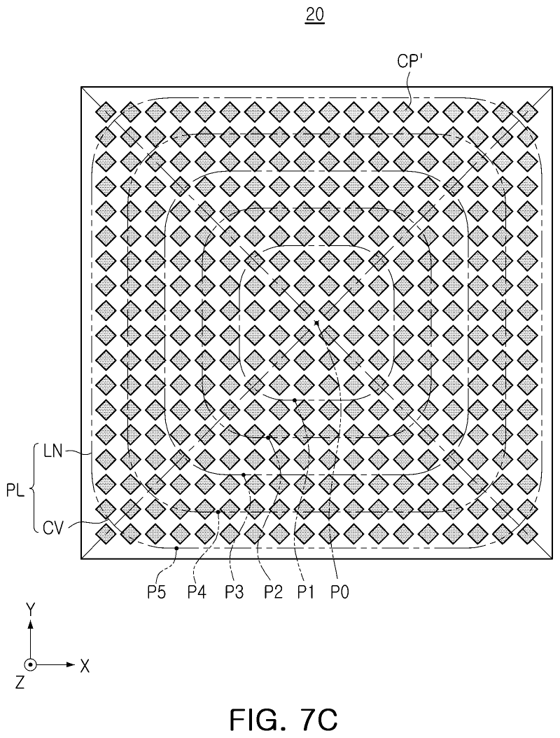

FIG. 7A is a diagram illustrating a change in a position of the peeling boundary PL of the dicing tape in the semiconductor device 100 of the exemplary embodiment, and FIGS. 7B and 7C are diagrams for illustrating a change in a position of the peeling boundary PL of the dicing tape in the semiconductor devices 10 and 20 of the first and second comparative examples.

Referring to FIG. 7A, the semiconductor device 100 of the exemplary embodiment may include a plurality of connection pads CP of which vertices are arranged toward the peeling boundary PL of the dicing tape. When the peeling boundary PL moves sequentially to positions P5, P4, P3, P2, P1, and P0, the reference pads FP may be disposed so that vertices at the positions P5, P4, P3, P2, P1, and P0 face the straight portion LN of the peeling boundary PL. In addition, the rotated pads RP may be disposed so that the vertices at positions P5, P4, P3, P2, P1, and P0 face the curved portion LV of the peeling boundary PL.

Referring to FIG. 7B, the semiconductor device 10 of the first comparative example may include a plurality of connection pads CP′, respective sides of which are disposed parallel to the edges E of the semiconductor device 10. When the peeling boundary PL moves sequentially to the positions P5, P4, P3, P2, P1, and P0, the connection pads CP′ of the first comparative example may be disposed so that sides thereof face the straight portion LN of the peeling boundary PL and vertices thereof face the curved portion LV of the peeling boundary PL.

Referring to FIG. 7C, the semiconductor device 20 of the second comparative example may include a plurality of connection pads CP′ disposed so that respective vertices face the edges E of the semiconductor device 10. When the peeling boundary PL moves sequentially to the positions P5, P4, P3, P2, P1, and P0, the connection pads CP′ of the second comparative example may be disposed so that respective sides face the curved portion LV of the peeling boundary PL and respective vertices thereof faces the straight portion LN of the peeling boundary PL.

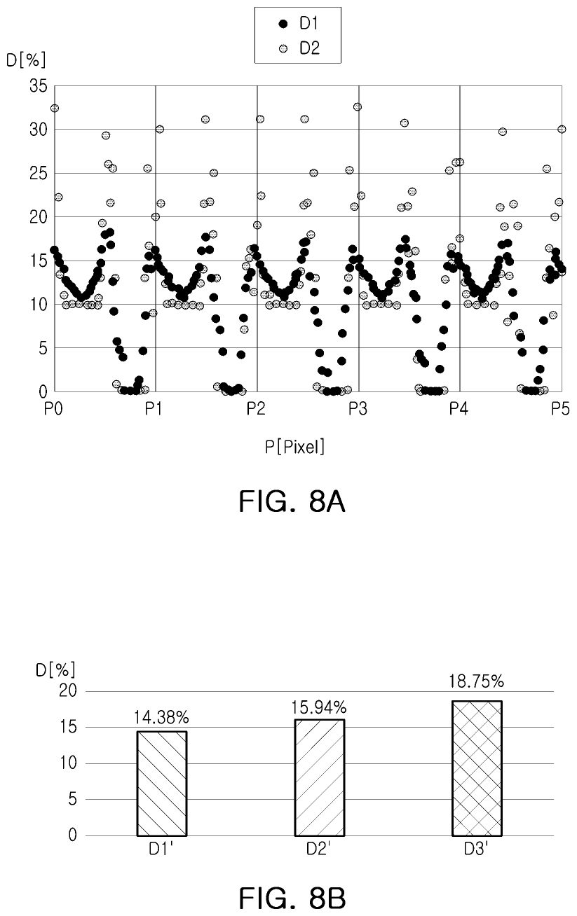

FIG. 8A is a graph illustrating a difference in peeling boundary density D between an example and a first comparative example, and FIG. 8B is a graph illustrating a difference in average peeling boundary density D between the example and the first and second comparative examples. FIGS. 8A and 8B illustrate peeling boundary density D depending on a position P of a peeling boundary PL.

Here, the peeling boundary density D may be defined as a ratio of a length by which the peeling boundary PL and connection pads CP and CP′ overlap to the total length of the peeling boundary PL at each position P5, P4, P3, P2, P1, and P0 may be understood to roughly correspond to the position of the peeling boundary PL illustrated in FIGS. 7A to 7C.

Peeling boundary density D1 of an example is a value calculated by dividing horizontal/vertical widths of the semiconductor device 100 into 500 pixels each for an arrangement of the connection pads CP similar to that of FIG. 7A.

Peeling boundary density D2 of a first comparative example is a value calculated by dividing horizontal/vertical widths of the semiconductor device 10 into 500 pixels each for an arrangement of the connection pads CP′ similar to that of FIG. 7B.

Referring to FIG. 8A, it can be seen that a maximum value of the peeling boundary density D1 of the example is mostly smaller than a maximum value of the peeling boundary density D2 of the first comparative example. In addition, it can be seen that a variation in the peeling boundary density D1 of the example is smaller than that of the peeling boundary density D2 in the first comparative example. This can be understood in that overlap of the reference pads FP with a straight portion LN of the peeling boundary PL is minimized, and overlap of the rotated pads RP with a curved portion LV of the peeling boundary PL is also minimized.

Referring to FIG. 8B, average peeling boundary density D1′ in the example is about 14.38%, average peeling boundary density D2′ in the first comparative example is about 15.94%, and average peeling boundary density D3′ in the second comparative example is about 18.75%. Here, the average peeling boundary density D3′ in the second comparative example can be understood as an average value of the peeling boundary density in the second comparative example calculated similarly to the above-mentioned one. For example, the peeling boundary density in the second comparative example may be calculated by dividing the horizontal/vertical width of the semiconductor device 20 into 500 pixels each for an arrangement of the connection pad CP′ similar to that of FIG. 7C. When vertices of the plurality of connection pads CP′ are disposed to face edges E of the semiconductor device 10 in the second comparative example, it can be seen that the average peeling boundary density is increased rather than the case in which the sides of the plurality of connection pads CP′ are disposed parallel to the edges E of the semiconductor device in the first comparative example. In contrast thereto, when rotated pads RP are disposed in the curved portion LV of the peeling boundary PL in the example, it can be seen that the average peeling boundary density D1′ is reduced compared to the average peeling boundary density D2′ in the first comparative example and the average peeling boundary density D3′ in the second comparative example.

As set forth above, according to example embodiments of the present inventive concept, a semiconductor package having improved process efficiency may be provided by minimizing the peeling boundary density in a peeling direction of the dicing tape.

The various and advantageous advantages and effects of the present inventive concept are not limited to the above description, and may be more easily understood in the course of describing the specific embodiments of the present inventive concept.

While example embodiments have been shown and described above, it will be apparent to those skilled in the art that modifications and variations could be made without departing from the scope of the present invention as defined by the appended claims.

What is claimed is:

1. A semiconductor device, comprising:
a circuit layer including a front surface and a plurality of circuit edges defining the front surface; and
a plurality of conductive pads disposed on the front surface and having a polygonal planar shape,
wherein:
the plurality of conductive pads include a plurality of reference pads and a plurality of rotated pads,
each of the plurality of reference pads includes a reference pad surface, reference pad edges defining the reference pad surface, reference pad vertices and a reference pad diagonal which is a line segment joining a predetermined pair of the reference pad vertices,
the reference pad diagonal is disposed orthogonally to one of the plurality of circuit edges,
each of the plurality of rotated pads includes a rotated pad surface, rotated pad edges defining the rotated pad surface, rotated pad vertices and a rotated pad diagonal which is a line segment joining a predetermined pair of the reference pad vertices, the plurality of rotated pads include a first group of rotated pads including first to n^{th} rotated pads,
the plurality of reference pads include a first reference pad,
the first to n^{th} rotated pads are disposed in a series from one side of the first reference pad,
with respect to one of the plurality of circuit edges, each of the first to n^{th} rotated pads has a rotation angle (βn) substantially given by an equation:
$$βn = n ( 45 ° / N ) ,$$
and
in the equation above, n represents an arrangement order of the first to n^{th} rotated pads, and N is a number of the first to n^{th} rotated pads.

2. The semiconductor device of claim 1, wherein:
the plurality of circuit edges include a first circuit edge,
the first reference pad is located adjacent to the first circuit edge, and
the first reference pad and the first to n^{th} rotated pads are linearly arranged along and parallel to the first circuit edge.

3. The semiconductor device of claim 1, wherein:
the front surface includes front surface vertices and a front surface diagonal which is a line segment joining a predetermined pair of the front surface vertices, and
the front surface diagonal aligns with the rotated pad diagonal of the n^{th} rotated pad.

4. The semiconductor device of claim 1, wherein:
the plurality of circuit edges include a first circuit edge and a second circuit edge, intersecting each other,
the plurality of reference pads include a first group of reference pads adjacent to the first circuit edge in a first direction, and a second group of reference pads adjacent to the second circuit edge in a second direction perpendicular to the first direction,
the plurality of rotated pads further include a second group of rotated pads including first to k^{th} rotated pads, and the first to k^{th} rotated pads are disposed in a series, and
the first group of reference pads includes the first reference pad, and the second group of reference pads includes a second reference pad.

5. The semiconductor device of claim 4, wherein the first to k^{th} rotated pads extend in a straight line from one side of the n^{th} rotated pad of the first group of rotated pads to the second reference pad.

6. The semiconductor device of claim 5, wherein:
a number of pads of the first group of rotated pads is 1 greater than a number of pads of the second group of rotated pads, and
the n^{th} rotated pad is disposed on the front surface diagonal.

7. The semiconductor device of claim 4, wherein:
the front surface includes front surface vertices and a front surface diagonal which is a line segment joining a predetermined pair of the front surface vertices,
each of the plurality of rotated pads has a rotation angle with respect to one of the plurality of circuit edges, and
in view of the rotation angle, the first to n−1^{th} of the first group of rotated pads are arranged symmetrically to the first to k^{th} rotated pads of the second group of rotated pads with respect to the front surface diagonal in a plan view.

8. The semiconductor device of claim 1, wherein:
the front surface includes front surface vertices,
at least a group of the plurality of the reference pads are disposed within a first region adjacent to a central portion of one of circuit edges in a plan view, and
at least a group of the plurality of the rotated pads are disposed within a second region adjacent to one of the front surface vertices in a plan view.

9. The semiconductor device of claim 1, wherein:
the polygonal planar shape of the plurality of conductive pads is a square shape.

10. The semiconductor device of claim 1, further comprising:
a semiconductor substrate; and
discrete devices disposed on the semiconductor substrate,
wherein the circuit layer includes:
an interconnection structure electrically connecting at least a group of the plurality of conductive pads to the discrete devices, and
an interlayer insulating layer covering the discrete devices and the interconnection structure.

11. A semiconductor device, comprising:
a circuit layer including a front surface, circuit edges defining the front surface, front surface vertices and a front surface diagonal which is a line segment joining a predetermined pair of the front surface vertices; and
a plurality of conductive pads disposed on the front surface, each conductive pad having a square planar shape,
wherein:
the plurality of conductive pads include reference pads and rotated pads,
the rotated pads include first to n^{th} rotated pads,
the first to n−1^{th} rotated pads are disposed between the reference pads and the front surface diagonal,
each of the reference pads includes a reference pad surface and reference pad edges defining the reference pad surface,
for each reference pad, a predetermined one of the reference pad edges has a reference angle with respect to a particular one of the circuit edges,
each of the rotated pads includes a rotated pad surface and rotated pad edges defining the rotated pad surface,
for each rotated pad, a predetermined one of the rotated pad edges has an inclination angle with respect to the particular one of the circuit edges, and the inclination angle is smaller than the reference angle, and
as the rotated pads get closer to the front surface diagonal, the inclination angles of the rotated pads decrease.

12. The semiconductor device of claim 11, wherein:
the reference pads include a first reference pad,
the first to n^{th} rotated pads are sequentially arranged from one side of the first reference pad to the front surface diagonal,
each of the first to n^{th} rotated pads are disposed such that the predetermined one of the rotated pad edges has the inclination angle (an) which is substantially given by an equation:
$${α}_{n} = 45 ° - n ( 45 ° / N ) ,$$
and
in the equation above, n represents an arrangement order of the first to n^{th} rotated pads, and N is a number of the first to n^{th} rotated pads.

13. The semiconductor device of claim 12, wherein the n^{th} rotated pad is disposed on the front surface diagonal.

14. The semiconductor device of claim 12, wherein the n^{th} rotated pad has at least one rotated pad edge parallel to the particular one of the circuit edges.

15. The semiconductor device of claim 11, wherein the reference angle is about 45°.

16. The semiconductor device of claim 11, wherein:
the reference pads include a first reference pad and a second reference pad,
the first reference pad is spaced apart from the particular one of the circuit edges by a first distance in a first direction,
the second reference pad is spaced apart from the particular one of the circuit edges by a second distance in the first direction, and the second distance is greater than the first distance,
the rotated pads include first and second set of rotated pads, the first set of rotated pads is disposed on one side of the first reference pad, and the second set of rotated pads is disposed on one side of the second reference pad,
the first set of rotated pads includes first to n^{th} rotated pads sequentially arranged in a second direction perpendicular to the first direction on the one side of the first reference pad,
the second set of rotated pads includes first to m^{th} rotated pads sequentially arranged in the second direction on the one side of the second reference pad, and
the n^{th} rotated pad and the m^{th} rotated pad are disposed on the front surface diagonal.

17. The semiconductor device of claim 16, wherein:
the first reference pad and the second reference pad are disposed on a line parallel to the front surface diagonal, and
the number n is the same as the number m.

18. The semiconductor device of claim 16, wherein the first reference pad and the second reference pad are disposed on a line perpendicular to the particular one of the circuit edges.

19. A semiconductor device, comprising:
a circuit layer including a front surface, circuit edges defining the front surface, front surface vertices and a front surface diagonal which is a line segment joining a predetermined pair of the front surface vertices; and
a plurality of conductive pads disposed on the front surface and having a polygonal planar shape,
wherein:
the plurality of conductive pads include reference pads and rotated pads,
each of the reference pads includes a reference pad surface and reference pad edges defining the reference pad surface,
each of the rotated pads includes a rotated pad surface, rotated pad edges defining the rotated pad surface, rotated pad vertices and a rotated pad diagonal which is a line segment joining a predetermined pair of the rotated pad vertices,
with respect to a particular one of the circuit edges, each of the reference pads includes at least one reference pad edge having a reference angle (0) substantially given by a first equation:
$$θ = 180 ° / z ,$$
in the first equation, z is a number of the reference pad edges of one of the reference pads, and
at least one of the rotated pads includes the reference pad diagonal which aligns with the front surface diagonal.

20. The semiconductor device of claim 19, wherein:
the reference pads include a first reference pad,
the rotated pads include first to n^{th} rotated pads sequentially arranged from one side of the first reference pad,
with respect to a reference line orthogonal to the particular one of the circuit edges, the rotated pad diagonal of each of the first to n^{th} rotated pads has a rotation angle (βn) substantially given by a second equation:
$${β}_{n} = n ( 45 ° / N ) ,$$
and
in the second equation, n represents an arrangement order of the first to n^{th} rotated pads, and N is a number of the first to n^{th} rotated pads.
